(19) United States
(12) Patent Application Publication
(10) Pub. No.: US 2012/0007479 A1
(43) Pub. Date: Jan. 12, 2012

(54) CASE HAVING SUPPORT DEVICE

(75) Inventor: Jin-Sung Park, Yongin-si (KR)

(73) Assignee: SAMSUNG SDI CO., LTD., Yongin-si (KR)

(21) Appl. No.: 12/985,103

(22) Filed: Jan. 5, 2011

(30) Foreign Application Priority Data
Jul. 12, 2010 (KR) 10-2010-0066858

(51) Int. Cl. H05K 5/02; F16B 47/00

(52) U.S. Cl. 312/223.2

(57) ABSTRACT

A case of a portable computing device is disclosed. The case includes: a case body including a bottom wall, which includes a hole, a support device including a support portion and an insert portion integral with the support portion, and where the support device is engaged with the case such that the insert portion is inserted through the hole while the support portion is positioned over an exterior surface of the bottom wall, where the support portion is bonded to the exterior surface with an adhesive.

### CROSS-REFERENCE TO RELATED APPLICATIONS

This application claims priority to and the benefit of Korean Patent Application No. 10-2010-0066858, filed on Jul. 12, 2010, in the Korean Intellectual Property Office, the entire content of which is incorporated herein by reference.

### BACKGROUND

1. Field

The present disclosure relates to a case of an electronic device.

2. Description of the Related Technology

In general, users use portable computers or computing devices on a surface, such as a desk or floor. The portable computers or devices are generally provided with a supporting member at the bottom, made of material such as rubber, in order to prevent the portable computer from sliding or moving on the surface.

The supporting member is generally manufactured by double injection molding with the bottom of the portable computers, but the manufacturing cost can be high. The supporting member may also be attached to the bottom of the portable computers by attaching a tab on the supporting member, but the supporting member may be detached from the bottom of the portable computers, because the bonding force may be small.

### SUMMARY OF CERTAIN INVENTIVE ASPECTS

An embodiment provides a case having a supporting member (or support device) that can increase fastening strength by attaching the supporting member to the bottom of the case of portable computers or computing devices, by using a soldering iron and/or an adhesive.

One aspect is a case of a portable computing device, the case including: a case body including a bottom wall, which includes a hole, a support device including a support portion and an insert portion integral with the support portion, and where the support device is engaged with the case such that the insert portion is inserted through the hole while the support portion is positioned over an exterior surface of the bottom wall, where the support portion is bonded to the exterior surface with an adhesive.

The insert portion of the support device may be melted to form a soldered body configured to prevent the support device from being disengaged from the hole.

The adhesive may be a material selected from the group consisting of acrylic resin, α-olefin resin, polyuretheane resin, polyimide resin and epoxy resin.

The hole may be smaller than a horizontal circumference of the support portion of the support device.

The support device may be made of rubber.

Another aspect is a case of a portable computing device, the case including: a case body including a bottom wall, which includes an interior surface, an exterior surface, a through-hole and a protrusion protruding from the interior surface next to the through-hole, and a support device including an insert portion and a support portion integral with the insert portion, where the support device is engaged with the case such that the insert portion and the protrusion are integrated as a soldered body configured to prevent the support device from being disengaged from the hole, whereas the support portion is located over the exterior surface of the bottom wall.

The support portion may be bonded to the exterior surface by an adhesive.

The adhesive may be selected from the group consisting of acrylic resin, α-olefin resin, polyuretheane resin, polyimide resin and epoxy resin.

The hole may be smaller than a horizontal circumference of the support portion.

The protrusion may be protruding from the interior surface around the through-hole.

The protrusion may be melted together with the insert portion.

The protrusion may not be melted, and the insert portion may be melted to form the soldered body.

The support device may be made of rubber.

According to an aspect, there is provided a case having a supporting member, which includes: a case having at least one holes in the bottom and defining the external shape of a portable computer; and a supporting member having an inserting portion that is inserted in the hole of the case and a supporting portion that contacts the bottom of the case, extending from the insertion portion, in which the case and the supporting member are combined by disposing an adhesive on the surface of the supporting member which contacts the case.

Further, the inserting portion may be melted by a soldering iron, after the case and the supporting member are combined.

In this configuration, the adhesive may be made of any one selected from a group of acrylic resin, α-Olefin resin, polyuretheane resin, polyimide and epoxy resin.

Further, the size of the hole of the case may be smaller than the horizontal circumference of the supporting member.

Further, the supporting member may be made of rubber.

According to another aspect, there is provided a case having a supporting member, which includes: a case defining the external shape of a laptop computer and having at least one hole and a protrusion protruding inward around the hole; and a supporting member having an inserting portion that is inserted in the hole of the case and a supporting portion that contacts the bottom of the case, in which the case and the supporting member are combined by melting the inserting portion of the supporting member and the protrusion with a soldering iron.

In this configuration, an adhesive may be further disposed on the surface of the supporting member which contacts the case.

Further, the size of the hole of the case may be smaller than the horizontal circumference of the supporting member.

As described above, it is possible to reduce manufacturing cost and increase fastening strength of a supporting member by attaching a supporting member to the bottom of a case of a portable computer, by using a soldering iron or an adhesive.

### BRIEF DESCRIPTION OF THE DRAWINGS

The accompanying drawings, together with the specification, illustrate exemplary embodiments of the present invention.

FIG. 1 is a perspective view showing a portable computer with a supporting member (or support device);

FIG. 2 is a perspective view showing an embodiment of a supporting member;

FIG. 3 is a bottom view showing a case of a portable computer;

FIG. 4 is a cross-sectional view taken along the line A-A′ of FIG. 1, and showing a case and a supporting member of a portable computer combined by an embodiment of an adhesive;

FIG. 5 is a cross-sectional view showing an embodiment of a supporting member;

FIG. 6 is a bottom view showing another embodiment of a case of a portable computer;

FIG. 7A is a cross-sectional view showing the other embodiment of the case and the supporting member before being melted;

FIG. 7B is a cross-sectional view showing the other embodiment of the case and the supporting member after being melted; and

FIG. 8 is a cross-sectional view showing the supporting member and the case combined according to another embodiment.

### DETAILED DESCRIPTION OF CERTAIN INVENTIVE EMBODIMENTS

In the following detailed description, only certain embodiments of the present invention have been shown and described, simply by way of illustration. As those skilled in the art would realize, the described embodiments may be modified in various ways, without departing from the spirit or scope of the present invention. Accordingly, the drawings and description are to be regarded as illustrative in nature and not restrictive. In addition, when an element is referred to as being “on” another element, it can be directly on the other element or be indirectly on the other element with one or more intervening elements interposed therebetween. Also, when an element is referred to as being “connected to” another element, it can be directly connected to the other element or be indirectly connected to the other element with one or more intervening elements interposed therebetween. Hereinafter, like reference numerals generally refer to like elements.

A case having a supporting member is described hereafter in detail with reference to the accompanying drawings showing certain embodiments of the present invention.

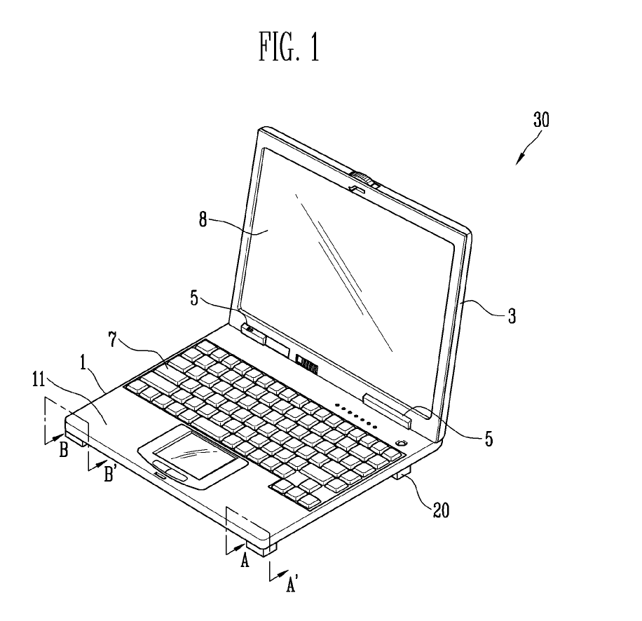

FIG. 1 is a perspective view showing a portable computer using a case with a supporting member (or support device) formed on the bottom of the computer.

Referring to FIG. 1, in general, secondary batteries can be used as batteries of portable computers and computing devices, such as laptop computers, tablet computers, and the like, which user can carry and use.

An embodiment of a portable computer 30 includes a main body 1 and a display unit 3. A supporting member (or support device) 20 made of rubber on the bottom of the main body 1 may be included to generate friction force against the surface on which the computer 30 is placed.

The main body 1 may include a case 11 defining the external shape of the computer 30, and the supporting member 20 may be formed on the bottom of the case 11. In some embodiments, the supporting member 20 may be formed at four corners of the bottom of the computer 30.

The main body 1 and the display unit 3 may be connected by a hinge unit 5 such that the display unit 3 may be folded on the main body 1 for storing. The portable computer may be unfolded to be used.

The main body 1 may be formed in a substantially flat shape and various components including a main substrate may be installed in a space therein. An input device, such as a keyboard 7, may be formed on the top surface of the main body 1. The display unit 3 may include a display panel 8. In some embodiments, a liquid crystal may be used for the display panel 8. Signal connection between the display unit 3 and the main body 1 may also be achieved by the hinge unit 5.

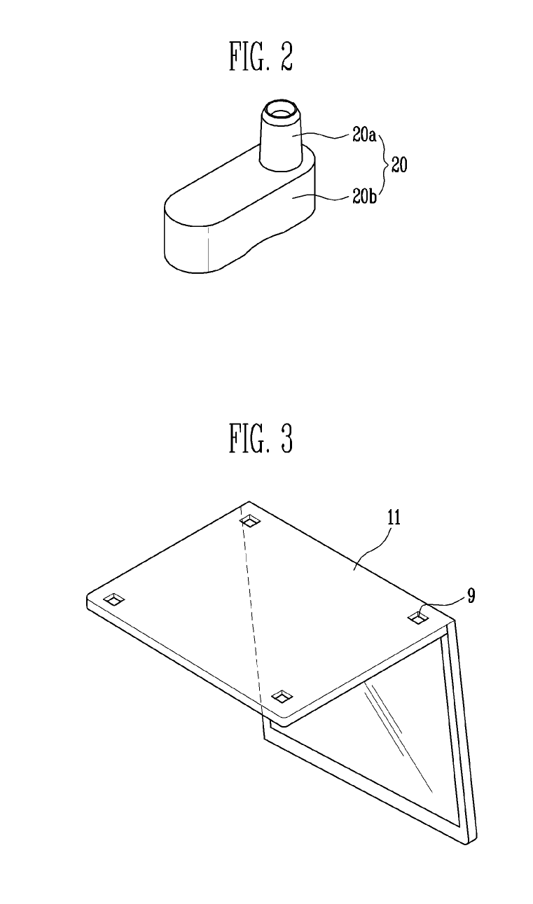

FIG. 2 is a perspective view showing an embodiment of a supporting member.

Referring to FIG. 2, an embodiment of the supporting member 20 may be composed of an inserting portion (or insert portion) 20a and a supporting portion (or support portion) 20b. In this configuration, the inserting portion 20a is inserted and fixed in a hole (9, 9′ in FIGS. 3 and 6) formed in the bottom of the case 11. The supporting portion 20b extends from the inserting portion 20a, with one side in contact with the bottom of the case 11 and the other side being in contact with the surface on which the computer is placed. In some embodiments, the inserting portion 20a and the supporting portion 20b may be integrally made of rubber, and the circumference of the supporting member 20b may be larger than the inserting portion 20a.

FIG. 3 is a bottom view showing a case of a portable computer.

Referring to FIG. 3, holes 9 are formed at four corners of the bottom of the case 11. The inserting portion 20a of the supporting member 20 (see FIG. 2) may be inserted in the hole 9 and the supporting member 20b may be exposed outside the case 11. The supporting member 20 is inserted in the hole and can generate friction force between the bottom of the portable computer and the surface where the computer is placed.

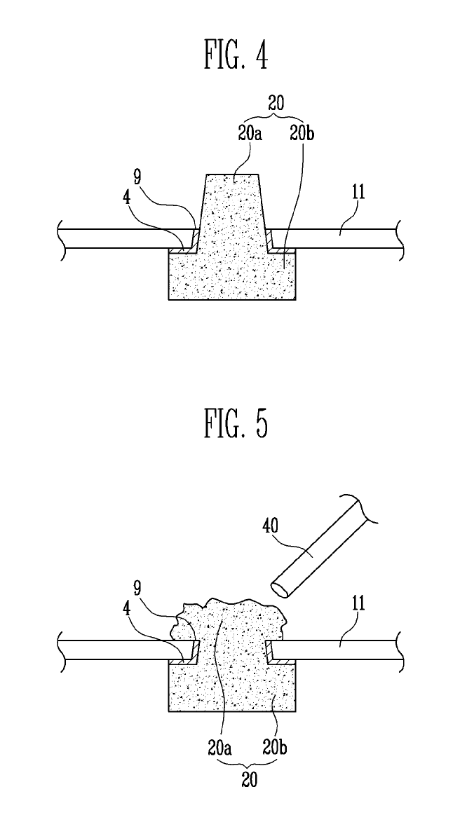

FIG. 4 is a cross-sectional view taken along the line A-A′ of FIG. 1, and showing a case and a supporting member combined by an embodiment of an adhesive.

Referring to FIG. 4, the supporting member 20 made of rubber is inserted in each of the holes 9 formed in the bottom of the case 11. The supporting member 20 has the inserting portion 20a that is inserted in the hole 9 of the case 11 and the supporting portion 20b that extends from the inserting portion 20a to contact the bottom of the case 11.

In some embodiments, the size of the hole 9 of the case 11 may be smaller than the circumference of the supporting portion 20b of the supporting member 20. Accordingly, only the inserting portion 20a of the supporting member 20 is inserted in the hole 9 and the supporting portion 20b contacts the bottom of the case 11 to generate friction force against the surface on which the portable computer is placed.

With the supporting member 20 inserted into the bottom of the case 11, the case 11 and the supporting member 20 are combined by disposing an adhesive 4 on the surface of the supporting member 20 which contacts the case 11. In some embodiments, the adhesive 4 is disposed where the hole 9 of the case 11 and the inserting portion 20a are in contact, and where the bottom of the case 11 and the supporting portion 20b are in contact.

In some embodiments, the adhesive 4 may be made of acrylic resin, α-Olefin resin, polyuretheane resin, polyimide, epoxy resin, or the like.

Using the supporting member 20 described above along with the adhesive 4 on the bottom of the case 11 may increase the fastening strength when compared with using a tab.

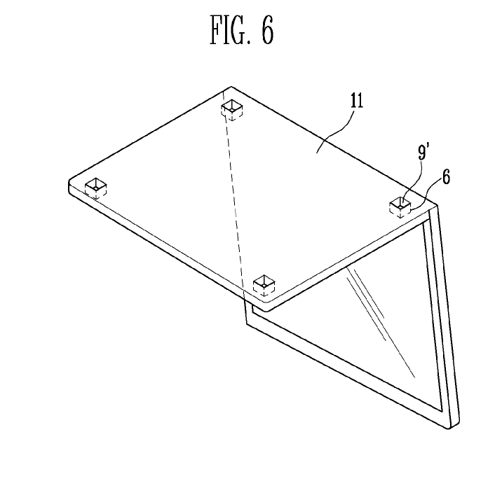

FIG. 5 is a cross-sectional view showing an embodiment of the supporting member. In FIG. 5, the supporting member 20 is melted using a soldering iron after attaching the adhesive 4.

Referring to FIG. 5, the supporting member 20 combined to the case 11 using the adhesive 4 is melted inside the case. The inserting portion 20a inserted in the hole 9 is melted using a soldering iron 40. Accordingly, the inserting portion 20a made of rubber adheres to the inside the case 11 inside the hole 9. As the inserting portion 20a is melted and adheres to the inside of the case 11, the gap between the hole 9 and the inserting portion 20a disappears. Accordingly, the fastening strength can be further increased, as compared with when the case 11 and the supporting member 20 are combined using only the adhesive 4.

FIG. 6 is a bottom view showing another embodiment of a case of a portable computer.

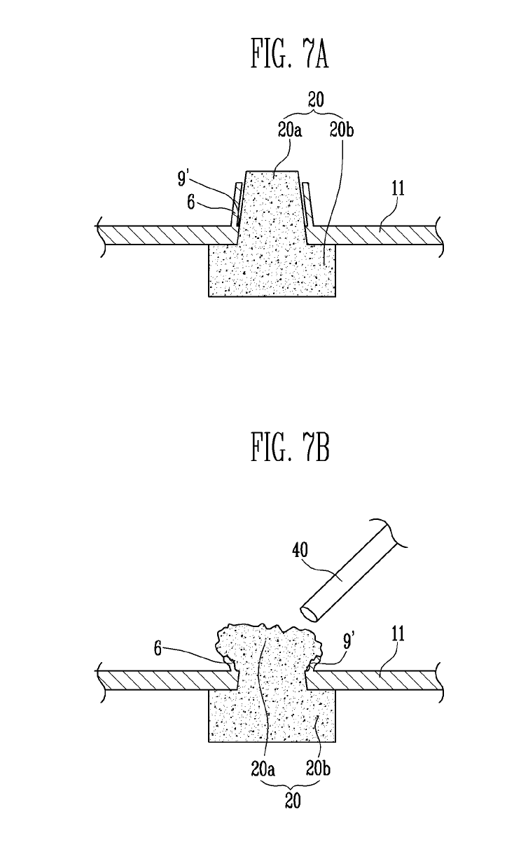

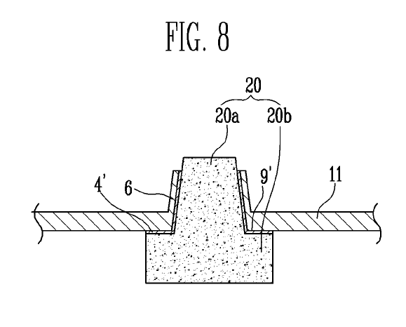

Referring to FIG. 6, holes 9′ and protrusions 6 protruding into a case 11 are formed at four corners at the bottom of the case 11. The inserting portion 20a of the supporting member 20 (see FIG. 2) is inserted in each of the holes 9′ and the supporting member 20b is exposed outside the case 11. An embodiment of a method of combining the case 11 of FIG. 6 with the supporting member 20 is described in detail below with reference to FIGS. 7 and 8.

FIG. 7A and FIG. 7B are cross-sectional views showing the case and the supporting member before and after being melted.

Referring to FIGS. 7A and 7B, the supporting member 20 is inserted in the hole 9′ formed in the bottom of the case 11. The inserting portion 20a of the supporting member 20 is inserted in the hole 9′ and may be in internal contact with the protrusion 6 protruding into the case 11, around the hole 9′. The supporting portion 20b extending from the inserting portion 20a and positioned outside the bottom of the case 11 prevents the bottom of the case 11 from sliding on the surface on which the portable computer is placed.

In order to combine the case 11 with the supporting member 20, the inserting portion 20a and the protrusion 6 are melted using a soldering iron 40, at the inserting portion 20a of the supporting member 20. Accordingly, the inserting portion 20a and the protrusion 6 are melted and clotted, such that case 11 and the supporting member 11 are combined. The melted inserting portion 20a and the protrusion 6 adhere to the inside of the case 11, at both sides of the hole 9′.

In some embodiments, the size of the hole 9′ may be smaller than the horizontal circumference of the supporting portion 20b of the supporting member 20. In some embodiments, the soldering iron 40 is heated enough to melt only the inserting portion 20a of the supporting member 20 and the protrusion 6.

FIG. 8 is a cross-sectional view showing an embodiment of the supporting member and the case combined by soldering or using an adhesive.

Referring to FIG. 8, in some embodiments, an adhesive 4′ may be further disposed on the surface of the supporting member 20 which contacts the case 11, before the protrusion 6 and the inserting portion 20a are melted by the soldering iron. The adhesive 4′, may be made of any one selected from a group of acrylic resin, α-Olefin resin, polyuretheane resin, polyimide, epoxy resin and the like.

In such embodiments, it may be possible to more easily melt the protrusion 6 and the inserting portion 20a with the soldering iron 40, by fixing the protrusion 6 and the inserting portion 20a with the adhesive 4′ before melting.

While the present invention has been described in connection with certain embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A case of a portable computing device, the case comprising:
a case body comprising a bottom wall, which comprises a hole;
a support device comprising a support portion and an insert portion integral with the support portion; and
wherein the support device is engaged with the case such that the insert portion is inserted through the hole while the support portion is positioned over an exterior surface of the bottom wall;
wherein the support portion is bonded to the exterior surface with an adhesive.

2. The case as claimed in claim 1, wherein the insert portion of the support device is melted to form a soldered body configured to prevent the support device from being disengaged from the hole.

3. The case as claimed in claim 1, wherein the adhesive is a material selected from the group consisting of acrylic resin, α-olefin resin, polyuretheane resin, polyimide resin and epoxy resin.

4. The case as claimed in claim 1, wherein the hole is smaller than a horizontal circumference of the support portion of the support device.

5. The case as claimed in claim 1, wherein the support device is made of rubber.

6. A case of a portable computing device, the case comprising:
a case body comprising a bottom wall, which comprises an interior surface, an exterior surface, a through-hole and a protrusion protruding from the interior surface next to the through-hole; and
a support device comprising an insert portion and a support portion integral with the insert portion;
wherein the support device is engaged with the case such that the insert portion and the protrusion are integrated as a soldered body configured to prevent the support device from being disengaged from the hole, whereas the support portion is located over the exterior surface of the bottom wall.

7. The case as claimed in claim 6, wherein the support portion is bonded to the exterior surface by an adhesive.

8. The case as claimed in claim 7, wherein the adhesive is selected from the group consisting of acrylic resin, α-olefin resin, polyuretheane resin, polyimide resin and epoxy resin.

9. The case as claimed in claim 6, wherein the hole is smaller than a horizontal circumference of the support portion.

10. The case as claimed in claim 6, wherein the protrusion is protruding from the interior surface around the through-hole.

11. The case as claimed in claim 6, wherein the protrusion is melted together with the insert portion.

12. The case as claimed in claim 6, wherein the protrusion is not melted, and the insert portion is melted to form the soldered body.

13. The case as claimed in claim 6, wherein the support device is made of rubber.
